(19) United States
(12) Patent Application Publication
(10) Pub. No.: US 2026/0088769 A1
(43) Pub. Date: Mar. 26, 2026

(54) INPUT NETWORK FOR DOHERTY POWER AMPLIFIER

(71) Applicant: QUALCOMM Incorporated, San Diego, CA (US)

(72) Inventors: Doohwan JUNG, Huntington Beach, CA (US); Hirad SAMAVATI, Santa Clara, CA (US); Shahram ABDOLLAHI-ALIBEIK, Los Gatos, CA (US); Kwan-Woo KIM, Palo Alto, CA (US); Kamal AGGARWAL, Pleasanton, CA (US); Amaresh HEGGADDE SHIVANANDA, Santa Clara, CA (US)

(21) Appl. No.: 18/895,090

(22) Filed: Sep. 24, 2024

(51) Int. Cl. H03F 1/02; H03F 3/24; H04B 1/04

(52) U.S. Cl. CPC H03F 1/0288; H03F 3/245; H04B 1/04; H03F 2200/451

(57) ABSTRACT

A Doherty power amplifier (PA) includes a main amplifier and an auxiliary amplifier. The Doherty PA also includes a first inductor coupled between a first input of the Doherty PA and a first input of the main amplifier, a second inductor coupled between a node and a first input of the auxiliary amplifier, wherein the second inductor is magnetically coupled with the first inductor, a third inductor coupled between a second input of the Doherty PA and a second input of the main amplifier, a fourth inductor coupled between the node and a second input of the auxiliary amplifier, wherein the fourth inductor is magnetically coupled with the third inductor. The Doherty PA further includes an output circuit coupled to an output of the main amplifier and an output of the auxiliary amplifier.

### BACKGROUND

### Field

Aspects of the present disclosure relate generally to wireless communications, and, more particularly, to power amplifiers.

### Background

A wireless device includes a transmitter for transmitting radio frequency (RF) signals via one or more antennas. The transmitter may include power amplifiers for amplifying the RF signals before transmission. One or more of the power amplifiers may be implemented with a Doherty power amplifier, which includes a main amplifier and an auxiliary amplifier.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a Doherty power amplifier (PA). The Doherty PA includes a main amplifier and an auxiliary amplifier. The Doherty PA also includes a first inductor coupled between a first input of the Doherty PA and a first input of the main amplifier, a second inductor coupled between a node and a first input of the auxiliary amplifier, wherein the second inductor is magnetically coupled with the first inductor, a third inductor coupled between a second input of the Doherty PA and a second input of the main amplifier, and a fourth inductor coupled between the node and a second input of the auxiliary amplifier, wherein the fourth inductor is magnetically coupled with the third inductor. The Doherty PA further includes an output circuit coupled to an output of the main amplifier and an output of the auxiliary amplifier, wherein the output circuit is configured to combine an output radio frequency (RF) signal from the output of the main amplifier and an output RF signal from the output of the auxiliary amplifier into a combined RF signal.

A second aspect relates to a system. The system includes a mixer configured to mix a baseband signal or an intermediate frequency (IF) signal with a local oscillator (LO) signal to generate a differential input radio frequency (RF) signal including a first input RF signal and a second input RF signal. The system also includes a Doherty power amplifier (PA) having a first input configured to receive the first RF signal and a second input configured to receive the second RF signal. The Doherty PA includes a main amplifier and an auxiliary amplifier. The Doherty PA also includes a first inductor coupled between the first input of the Doherty PA and a first input of the main amplifier, a second inductor coupled between a node and a first input of the auxiliary amplifier, wherein the second inductor is magnetically coupled with the first inductor, a third inductor coupled between the second input of the Doherty PA and a second input of the main amplifier, and a fourth inductor coupled between the node and a second input of the auxiliary amplifier, wherein the fourth inductor is magnetically coupled with the third inductor. The Doherty PA also includes an output circuit coupled to an output of the main amplifier and an output of the auxiliary amplifier, wherein the output circuit is configured to combine an output RF signal from the output of the main amplifier and an output RF signal from the output of the auxiliary amplifier into a combined RF signal.

### BRIEF DESCRIPTION OF THE DRAWINGS

FIG. 1 shows an example of a Doherty power amplifier including a main amplifier and an auxiliary amplifier according to certain aspects of the present disclosure.

FIG. 2 shows an example of a Doherty power amplifier with current combining according to certain aspects of the present disclosure.

FIG. 3 shows an example of a Doherty power amplifier with voltage combining according to certain aspects of the present disclosure.

FIG. 4 shows an example of an input circuit for a Doherty power amplifier according to certain aspects of the present disclosure.

FIG. 5A shows a closeup view of a portion of the input circuit of FIG. 4 according to certain aspects of the present disclosure.

FIG. 5B shows a closeup view of another portion of the input circuit of FIG. 4 according to certain aspects of the present disclosure.

FIG. 6A is a plot showing exemplary frequency responses of a low-pass filter path and a high-pass filter path in the input circuit according to certain aspects of the present disclosure.

FIG. 6B is a plot showing exemplary phase-frequency curves for first and second inputs of a main amplifier and exemplary phase-frequency curves for first and second inputs of an auxiliary amplifier according to certain aspects of the present disclosure.

FIG. 7A shows an example of a main amplifier, an auxiliary amplifier, and an output circuit according to certain aspects of the present disclosure.

FIG. 7B shows an example in which an impedance inverter is absorbed into a transformer in the output circuit according to certain aspects of the present disclosure.

FIG. 8A shows an example of a mixer coupled to a Doherty amplifier according to certain aspects of the present disclosure.

FIG. 8B shows an example of a driver amplifier between the mixer and the Doherty amplifier of FIG. 8A according to certain aspects of the present disclosure.

FIG. 9 is a diagram of an environment including an electronic device that includes a transceiver according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

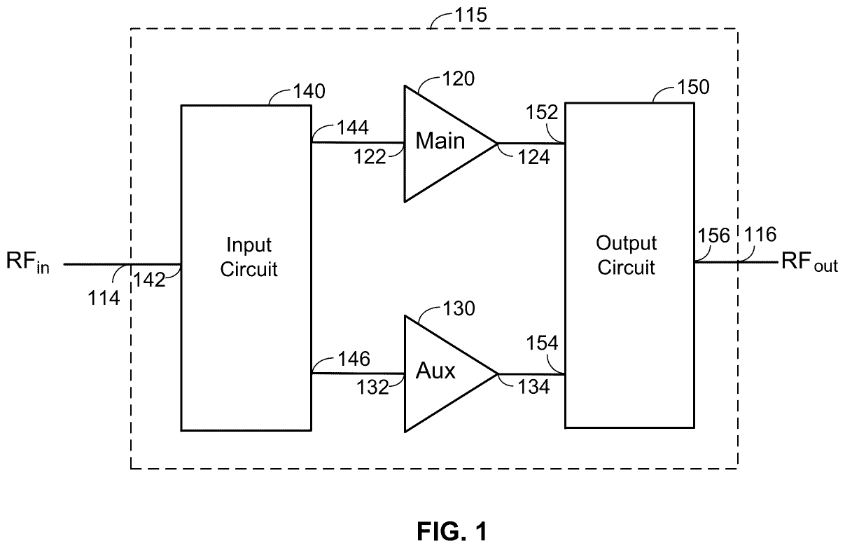

FIG. 1 shows an example of a Doherty power amplifier (PA) 115 according to certain aspects. The Doherty PA 115 may be included in a wireless device (e.g., a mobile device or a base station) for amplifying an RF signal before transmission via one or more antennas.

In the example in FIG. 1, the Doherty PA 115 has an input 114 and an output 116. The input 114 of the Doherty PA 115 is configured to receive an input RF signal RFᵢₙ. The input RF signal RFᵢₙ may come from a mixer (not shown) configured to frequency upconvert a baseband signal or an intermediate frequency (IF) signal into the input RF signal RFᵢₙ. The output 116 of the Doherty PA 115 may be coupled to an antenna (not shown). The Doherty PA 115 is configured to amplify the input RF signal RFᵢₙ, and output the resulting amplified RF signal RFₒᵤₜ at the output 116 for transmission via the antenna. The Doherty PA 115 may be used, for example, to provide efficient power amplification of an RF signal having a high peak-to-average power ratio (PAPR).

In the example shown in FIG. 1, the Doherty PA 115 includes an input circuit 140, a main amplifier 120, an auxiliary amplifier 130, and an output circuit 150. The main amplifier 120 may also be referred to as a carrier amplifier and the auxiliary amplifier 130 may also be referred to as a peaking amplifier. The input circuit 140 may also be referred to as an input network and the output circuit 150 may also be referred to as an output network.

The input circuit 140 has an input 142 coupled to the input 114 of the Doherty PA 115, a first output 144, and a second output 146. The main amplifier 120 has an input 122 coupled to the first output 144 of the input circuit 140, and an output 124. The auxiliary amplifier 130 has an input 132 coupled to the second output 146 of the input circuit 140, and an output 134. The output circuit 150 has a first input 152 coupled to the output 124 of the main amplifier 120, a second input 154 coupled to the output 134 of the auxiliary amplifier 130, and an output 156 coupled to the output 116 of the Doherty PA 115.

The input circuit 140 is configured to split the power of the input RF signal RFᵢₙ received at the input 142 between the first output 144 and the second output 146. In other words, the input circuit 140 is configured to split the input RF signal RFᵢₙ into a first RF signal and a second RF signal, output the first RF signal at the first output 144, and output the second RF signal at the second output 146.

The input circuit 140 is also configured to provide a phase shift between the first output 144 and the second output 146 (i.e., provide a phase shift between the first RF signal input to the main amplifier 120 and the second RF signal input to the auxiliary amplifier 130). In certain aspects, the phase shift is approximately equal to 90 degrees. The phase shift is used to provide phase compensation, as discussed further below.

The main amplifier 120 is configured to receive the first RF signal from the first output 144 of the input circuit 140 and amplify the first RF signal. The main amplifier 120 may be biased in class AB and may be on (i.e., active) when the main amplifier 120 is provided with a supply voltage. The auxiliary amplifier 130 is configured to receive the second RF signal from the second output 146 of the input circuit 140 (which is phase shifted (e.g., by 90 degrees) with respect to the first RF signal input to the main amplifier 120) and amplify the second RF signal. The auxiliary amplifier 130 may be biased in class C. In certain aspects, the auxiliary amplifier 130 may be configured to turn on when the main amplifier 120 is driven into saturation or close to saturation. A more detailed discussion of the main amplifier 120 and the auxiliary amplifier 130 is provided below.

The output circuit 150 is configured to combine the RF signals from the main amplifier 120 and the auxiliary amplifier 130, and output the combined RF signal RFₒᵤₜ at the output 116 for transmission via the antenna. The output circuit 150 may also provide impedance inversion to modulate the load at the output 124 of the main amplifier 120, as discussed further below. The impedance inversion introduces a 90-degree phase shift. The phase shift (e.g., 90-degree phase shift) in the input circuit 140 is used to compensate for the phase shift from the impedance inversion so that the RF signals from the main amplifier 120 and the auxiliary amplifier 130 are combined in phase.

As discussed above, the main amplifier 120 may be biased in class AB and the auxiliary amplifier 130 may be biased in class C, in which the main amplifier 120 may be on (i.e., active) when the main amplifier 120 is provided with a supply voltage, and the auxiliary amplifier 130 may be on when the main amplifier 120 is driven into saturation or close to saturation.

In operation, when the power level of the input RF signal RFᵢₙ is low, the auxiliary amplifier 130 is turned off and the main amplifier 120 provides amplification of the input RF signal. When the power level of the input RF signal RFᵢₙ is high enough to drive the main amplifier 120 into saturation or within some range of saturation, the auxiliary amplifier 130 turns on and provides additional amplification of the input RF signal RFᵢₙ. Thus, when the main amplifier 120 is driven into or close to saturation, both the main amplifier 120 and the auxiliary amplifier 130 contribute to amplification of the input RF signal RFᵢₙ. The impedance inversion in the output circuit 150 modulates the load at the output 124 of the main amplifier 120 in a manner that maintains high power efficiency as the main amplifier 120 operates in the saturation region.

In this example, the power efficiency of the Doherty PA 115 as a function of input power may have a first efficiency peak corresponding to a back-off power and a second efficiency peak corresponding to a peak power of the Doherty PA 115. The back-off power may be the power at which the main amplifier 120 enters saturation or close to saturation. In certain aspects, the back-off power may be approximately 6 dB below the peak power.

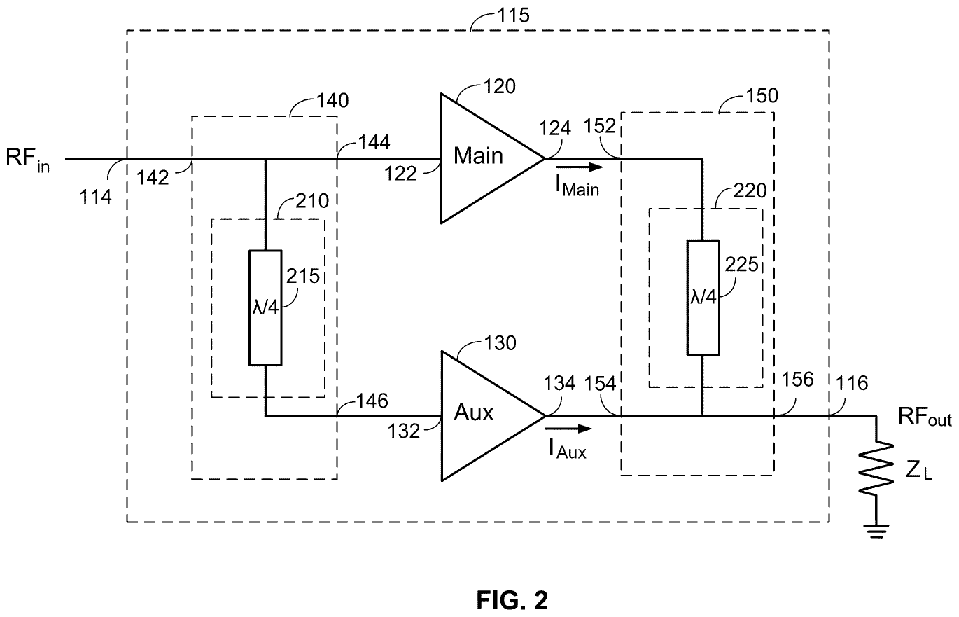

FIG. 2 shows an exemplary implementation of the input circuit 140 and the output circuit 150 according to certain aspects. In FIG. 2, the output 116 of the Doherty PA 115 is coupled to a load Z_{L}. The load Z_{L} may represent the load of an antenna, a transmission line, another component, or any combination thereof.

In this example, the input circuit 140 includes a 90-degree phase shifter 210 coupled between the input 114 of the Doherty PA 115 and the input 132 of the auxiliary amplifier 130. The phase shifter 210 provides a phase shift of 90 degrees between the input 122 of the main amplifier 120 and the input 132 of the auxiliary amplifier 130. As discussed further below, the phase shift provides phase compensation for the impedance inversion in the output circuit 150. In the example shown in FIG. 2, the phase shifter 210 is implemented with a quarter-wavelength transmission line 215. However, it is to be appreciated that the phase shifter 210 is not limited to this example. In other implementations, the phase shifter 210 may be implemented with a pi network including a series inductor and shunt capacitors, a resistor-capacitor capacitor-resistor (RC-CR) network, or another type of network.

In this example, the output circuit 150 includes an impedance inverter 220 coupled between the output 124 of the main amplifier 120 and the output 116 of the Doherty PA 115. The impedance inverter 220 modulates the load at the output 124 of the main amplifier 120 (e.g., lowers the load impedance) when the auxiliary amplifier 130 turns on to maintain high power efficiency as the main amplifier 120 operates in the saturation region. In the example shown in FIG. 2, the impedance inverter 220 is implemented with a quarter-wavelength transmission line 225. However, it is to be appreciated that the impedance inverter 220 is not limited to this example.

In this example, the impedance inverter 220 introduces a 90-degree phase shift. The phase shifter 210 in the input circuit 140 compensates for the phase shift by the impedance inverter 220 to provide in-phase power combining at the output 116.

FIG. 2 shows an example in which the output RF signals of the main amplifier 120 and the auxiliary amplifier 130 are combined using current combining to drive the load Z_{L}. In this example, the current of the main amplifier 120 (labeled “I_{Main}”) and the current of the auxiliary amplifier 130 (labeled “I_{Aux}”) are combined at the output 116 to drive the load Z_{L}. An output circuit employing current combining may be referred to as a current-combining output circuit or network, a parallel output circuit or network, or another term.

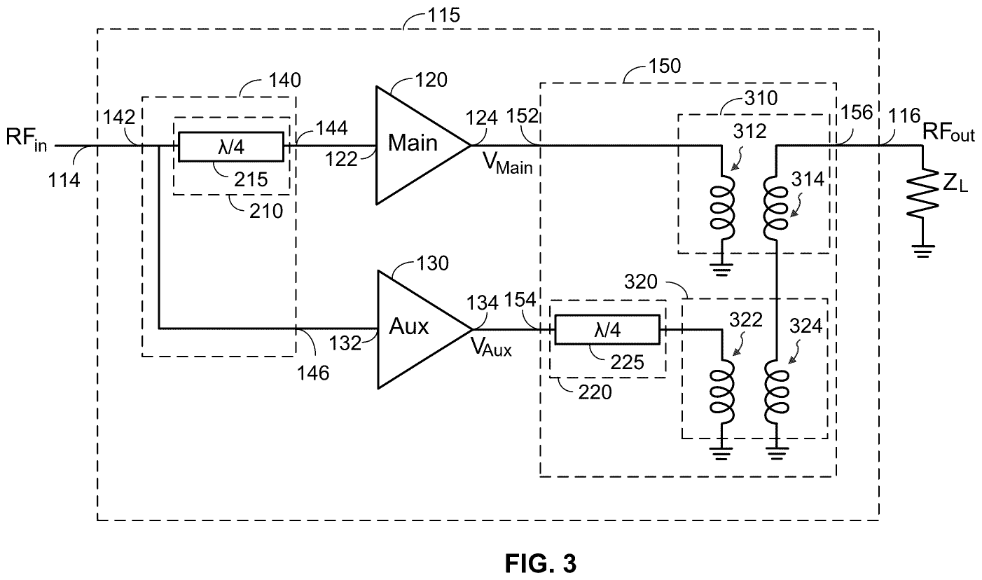

FIG. 3 shows another example in which the output RF signals of the main amplifier 120 and the auxiliary amplifier 130 are combined using voltage combining (also referred to as voltage-mode combining) to drive the load Z_{L}. In the example in FIG. 3, the phase shifter 210 in the input circuit 140 is coupled between the input 114 of the Doherty PA 115 and the input 122 of the main amplifier 120.

In this example, the output circuit 150 is implemented with a transformer-based output circuit including a first transformer 310 and a second transformer 320. The first transformer 310 includes a first inductor 312 and a second inductor 314 magnetically (i.e., inductively) coupled with the first inductor 312. The first inductor 312 is coupled to the output of the 124 of the main amplifier 120. The second transformer 320 includes a first inductor 322 and a second inductor 324 magnetically coupled with the first inductor 322. The impedance inverter 220 is coupled between the output 134 of the auxiliary amplifier 130 and the first inductor 322.

In this example, the second inductor 324 of the second transformer 320 is coupled in series with the second inductor 314 of the first transformer 310 to provide voltage combining at the output 116, in which the voltage of the main amplifier 120 (labeled “V_{Main}”) and the voltage the auxiliary amplifier 130 (labeled “V_{Aux}”) are combined. An output circuit employing voltage combining may be referred to as a voltage-combining output circuit or network, a series output circuit or network, or another term.

As discussed above, the input circuit 140 provides phase compensation for the phase shift introduced by the impedance inversion in the output circuit 150 in order to provide in-phase combining at the output 116. In the examples in FIGS. 2 and 3, the phase compensation is provided by the quarter-wavelength transmission line 215, which provides a phase shift of 90 degrees.

In other implementations, the phase shift may be provided using an RC-CR network where RC refers to resistor-capacitor and CR refers to capacitor-resistor. The RC-CR network provides a phase shift by splitting the input RF signal between a low-pass filter path (i.e., RC filter) and a high-pass filter path (i.e., CR filter). In this example, the phase shift between the low-pass filter path and the high-pass filter path is approximately 90 degrees at the frequency at which the frequency response of the low-pass filter path crosses the frequency response of the high-pass filter path. In this example, the resistances and capacitances in the RC-CR network may be selected such that frequency response of the low-pass filter path crosses the frequency response of the high-pass filter path at a frequency of the input RF signal to provide a phase shift of 90 degree.

However, the RC-CR network suffer from large signal losses due to resistors in the RF signal paths. In addition, the RC-CR may have difficulty handing the input impedance of the main amplifier and the auxiliary amplifier.

In other implementations, the input circuit of the Doherty PA includes a transmission-line coupler and two transformers at the inputs of the main amplifier and the auxiliary amplifier. However, the transmission-line coupler includes quarter-wavelength transmission lines, which take up a large chip area. In addition, the transmission-line coupler may require an additional ball (e.g., solder ball) on the chip to provide an external ground connection for isolation.

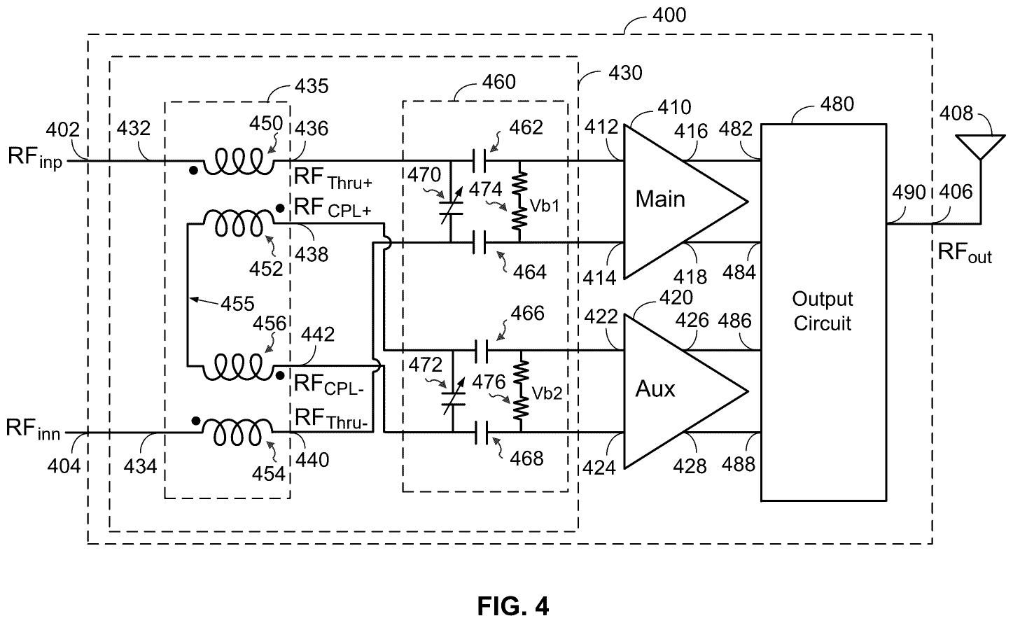

FIG. 4 shows an example of a Doherty power amplifier (PA) 400 according to certain aspects. The Doherty PA 400 includes an input circuit 430, a main amplifier 410, an auxiliary amplifier 420, and an output circuit 480. As discussed further below, the input circuit 430 overcomes drawbacks of the exemplary input circuits discussed above. The Doherty PA 400 may be included in a wireless device (e.g., a mobile device or a base station) for amplifying an RF signal before transmission via one or more antennas.

In the example in FIG. 4, the Doherty PA 400 has a differential input including a first input 402 and a second input 404. The differential input is configured to receive a differential input RF signal including a first input RF signal RFᵢₙₚ received at the first input 402 and a second input RF signal RFᵢₙₙ received at the second input 404. The Doherty PA 400 also has an output 406 coupled to an antenna 408. The Doherty PA 400 is configured to amplify the differential input RF signal, and output the resulting amplified RF signal RFₒᵤₜ at the output 406 for transmission via the antenna 408.

As discussed further below, the input circuit 430 (also referred to as an input network) is configured to split the differential input RF signal into a first differential RF signal and a second differential RF signal, in which the second differential RF signal is phase shifted with respect to the first differential RF signal (e.g., by 90 degrees). The first differential RF signal is input to the main amplifier 410 and the second differential RF signal is input to the auxiliary amplifier 420. The input circuit 430 is discussed in greater detail below according to certain aspects of the present disclosure.

The main amplifier 410 has a differential input including a first input 412 and a second input 414 and a differential output including a first output 416 and a second output 418. The differential input of the main amplifier 410 is configured to receive the first differential RF signal from the input circuit 430, as discussed further below. The main amplifier 410 may be biased in class AB and may be on (i.e., active) when the main amplifier 410 is provided with a supply voltage. The main amplifier 410 is configured to amplify the first differential RF signal and output the resulting amplified differential RF signal at the differential output of the main amplifier 410.

The auxiliary amplifier 420 has a differential input including a first input 422 and a second input 424 and a differential output including a first output 426 and a second output 428. The differential input of the auxiliary amplifier 420 is configured to receive the second differential RF signal from the input circuit 430 (which is phase shifted (e.g., by 90 degrees) with respect to the first differential RF signal input to the main amplifier 410). The auxiliary amplifier 130 may be biased in class C. The auxiliary amplifier 420 is configured to amplify the first differential RF signal and output the resulting amplified differential RF signal at the differential output of the auxiliary amplifier 420.

The output circuit 480 (also referred to as an output network) has a first input 482, a second input 484, a third input 486, a fourth input 488, and an output 490. The first input 482 and the second input 484 are coupled to the first output 416 and the second output 418, respectively, of the main amplifier 410. The third input 486 and the fourth input 488 are coupled to the first output 426 and the second output 428, respectively, of the auxiliary amplifier 420. The output 490 is coupled to the antenna 408.

The output circuit 480 is configured to combine the differential output RF signals from the main amplifier 410 and the auxiliary amplifier 420 into the combined RF signal RFₒᵤₜ, and output the combined RF signal RFₒᵤₜ at the output 490 for transmission via the antenna 408. For example, the output circuit 480 may be configured to combine the differential output RF signals from the main amplifier 410 and the auxiliary amplifier 420 into the combined RF signal RFₒᵤₜ using voltage combining. For example, the output circuit 480 may be implemented with a differential version of the exemplary output circuit 150 shown in FIG. 3 or another voltage-combining output circuit. However, it is to be appreciated that the output circuit 150 is not limited to a voltage-combining output circuit. For example, in other implementations, the output circuit 480 may be implemented with a current-combining output circuit.

The output circuit 480 employs load modulation using an impedance inverter to provide high power efficiency when the main amplifier 410 is driven in the saturation region. The impedance inverter introduces a phase shift (e.g., 90-degree phase shift). The input circuit 430 compensates for this phase shift in order to provide in-phase power combining at the output circuit 480.

In this example, the input circuit 430 includes a phase generator 435 and an AC coupling circuit 460. The phase generator 435 is configured to provide the phase shift between the first differential RF signal input to the main amplifier 410 and the second differential RF signal input to the auxiliary amplifier 420. For the example where the phase shift is 90 degrees, the phase generator 435 may also be referred to as a quadrature signal generator. As discussed above, the phase shift provides phase compensation for the phase shift in the output circuit 480.

The phase generator 435 has a first input 432 and a second input 434 configured to receive the differential input RF signal. More particularly, the first input 432 is configured to receive the first input RF signal RFᵢₙₚ of the differential input RF signal and the second input 434 is configured to receive the second input RF signal RFᵢₙₙ of the differential input RF signal. The phase generator 435 also has a first output 436, a second output 438, a third output 440, and a fourth output 442.

The phase generator 435 includes a first inductor 450, a second inductor 452, a third inductor 454, and a fourth inductor 456. The first inductor 450 is coupled between the first input 432 and the first output 436, and the second inductor 452 is coupled between a node 455 and the second output 438. The second inductor 452 is magnetically (i.e., inductively) coupled with the first inductor 450. In FIG. 4, the dots next to the first inductor 450 and the second inductor 452 indicate the polarities of the first inductor 450 and the second inductor 452.

The third inductor 454 is coupled between the second input 434 and the third output 440, and the fourth inductor 456 is coupled between the node 455 and the fourth output 442. The fourth inductor 456 is magnetically (i.e., inductively) coupled with the third inductor 454. In FIG. 4, the dots next to the third inductor 454 and the fourth inductor 456 indicate the polarities of the third inductor 454 and the fourth inductor 456. As discussed further below, the phase generator 435 is configured to provide a phase shift (e.g., 90-degree phase shift) between the first output 436 and the second output 438 and a phase shift (e.g., 90-degree phase shift) between the third output 440 and the fourth output 442.

In the example in FIG. 4, the second inductor 452 and the fourth inductor 456 are coupled in series between the first input 422 and the second input 424 of the auxiliary amplifier 420, in which the node 455 is between the second inductor 452 and the fourth inductor 456. In this example, the differential input RF signal creates a virtual ground or voltage reference at the node 455, which eliminates the need for an isolation port coupled to an additional ball (e.g., solder ball) on the chip to provide an external ground connection for isolation.

The AC coupling circuit 460 includes a first coupling capacitor 462, a second coupling capacitor 464, a third coupling capacitor 466, and a fourth coupling capacitor 468. The first coupling capacitor 462 is coupled between the first output 436 of the phase generator 435 and the first input 412 of the main amplifier 410 to AC couple the first output 436 of the phase generator 435 to the first input 412 of the main amplifier 410. The second coupling capacitor 464 is coupled between the third output 440 of the phase generator 435 and the second input 414 of the main amplifier 410 to AC couple the third output 440 of the phase generator 435 to the second input 414 of the main amplifier 410. The third coupling capacitor 466 is coupled between the second output 438 of the phase generator 435 and the first input 422 of the auxiliary amplifier 420 to AC couple the second output 438 of the phase generator 435 to the first input 422 of the auxiliary amplifier 420. The fourth coupling capacitor 468 is coupled between the fourth output 442 of the phase generator 435 and the second input 424 of the auxiliary amplifier 420 to AC couple the fourth output 442 of the phase generator 435 to the second input 424 of the auxiliary amplifier 420.

The AC coupling circuit 460 also includes a resistor 474 coupled between the first input 412 and the second input 414 of the main amplifier 410. The center tap of the resistor 474 is biased by bias voltage Vb1 to DC bias the inputs 412 and 414 of the main amplifier 410. The AC coupling circuit 460 also includes a resistor 476 coupled between the first input 422 and the second input 424 of the auxiliary amplifier 420. The center tap of the resistor 476 is biased by bias voltage Vb2 to DC bias the inputs 422 and 424 of the auxiliary amplifier 420.

In the example shown in FIG. 4, the AC coupling circuit 460 includes a capacitor 470 coupled between the first output 436 and the third output 440 and a capacitor 472 coupled between the second output 438 and the fourth output 442. The capacitors 470 and 472 may be implemented with tunable capacitors to provide additional tunability (e.g., to compensate for process variation). Also, the capacitors 470 and 472 may be sized to improve the efficiency of the Doherty PA 400. For example, each of the capacitors 470 and 472 may be implemented with a switchable capacitor bank (e.g., a two-bit capacitor bank) in which the capacitance of the capacitor is controlled by a digital control code.

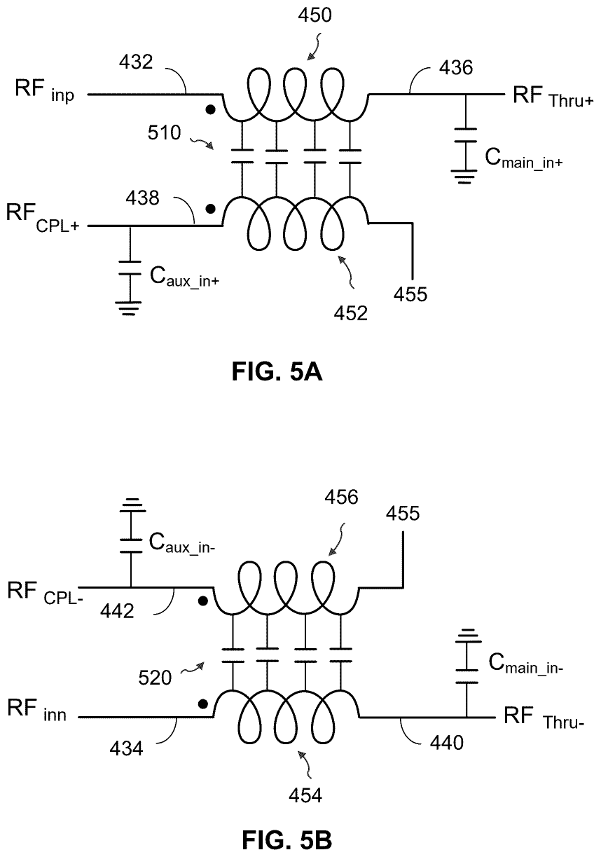

As discussed above, the phase generator 435 is configured to provide a phase shift (e.g., 90-degree phase shift) between the first output 436 and the second output 438 and a phase shift (e.g., 90-degree phase shift) between the third output 440 and the fourth output 442. In this regard, FIG. 5A shows a closeup view of the first inductor 450 and the second inductor 452 according to certain aspects. In this example, the first inductor 450 is coupled between the first input 432 and the first output 436, and the second inductor 452 is coupled between the node 455 (e.g., isolation node) and the second output 438. The second inductor 452 is also magnetically coupled with the first inductor 450. In FIG. 5A, the dots next to the first inductor 450 and the second inductor 452 indicate the polarities of the first inductor 450 and the second inductor 452.

The first inductor 450 and the second inductor 452 may each be implemented with a planar inductor (e.g., a planar spiral inductor, a loop inductor, etc.) integrated on the chip, in which the first inductor 450 and the second inductor 452 are placed close to each other to facilitate magnetic coupling between the first inductor 450 and the second inductor 452. The close proximity of the first inductor 450 and the second inductor 452 also results in capacitance between the first inductor 450 and the second inductor 452. In FIG. 5A, the capacitance is represented by the capacitors 510 between the first inductor 450 and the second inductor 452. FIG. 5A also shows capacitors representing the capacitance C_{main_in+} from the first input 412 of the main amplifier 410 and the capacitance C_{aux_in+} from the first input 422 of the auxiliary amplifier 420.

In this example, the first input RF signal RFᵢₙₚ is received at the first input 432 and split into RF signal RF_{Thru+} and RF signal RF_{CPL+}. The RF signal RF_{Thru+} propagates through the first inductor 450 along a path from the first input 432 to the first output 436. The RF signal RF_{Thru+} is coupled to the first input 412 of the main amplifier 410 (shown in FIG. 4). The RF signal RF_{CPL+} propagates along a path from the first input 432 to the second output 438 via magnetic and capacitive coupling. The RF signal RF_{CPL+} is coupled to the first input 422 of the auxiliary amplifier 420 (shown in FIG. 4).

In this example, the path from the first input 432 to the first output 436 provides a low-pass filter path and the path from the first input 432 to the second output 438 provides a high-pass filter path. This is because the capacitors 510 (which model the capacitance between the inductors 450 and 452) act as shunt capacitors for the path from the first input 432 to the first output 436 and the capacitors 510 act as series capacitors for the path from the first input 432 to the second output 438. In this example, the phase shift between the low-pass filter path and the high-pass filter path (i.e., the first output 436 and the second output 438) is approximately 90 degrees at the frequency at which the frequency response of the low-pass filter path crosses the frequency response of the high-pass filter path.

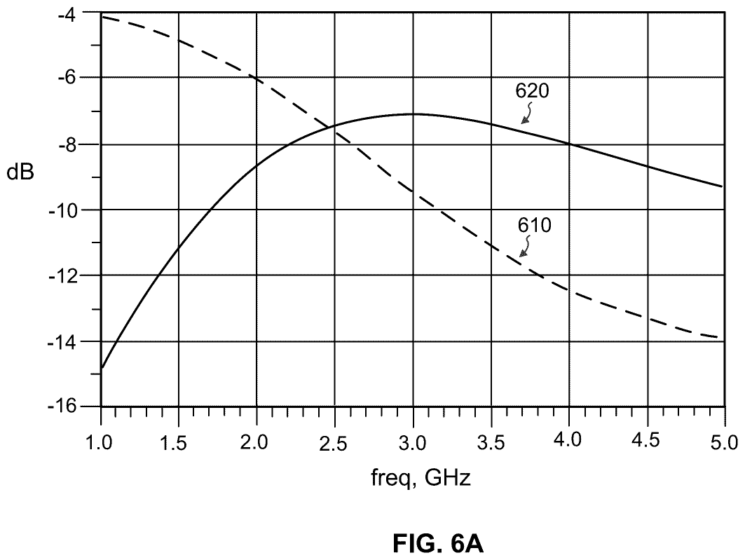

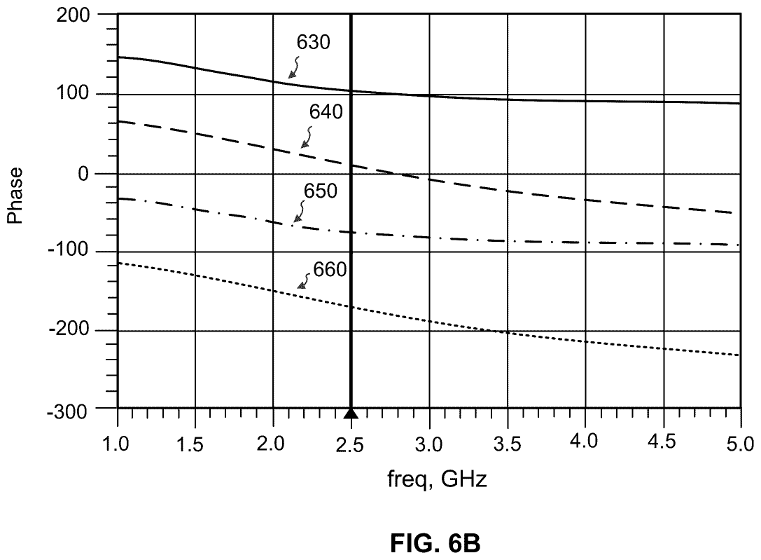

In this regard, FIG. 6A shows a plot illustrating an example of the frequency response 610 of the low-pass filter path and the frequency response 620 of the high-pass filter path. In this example, the frequency response 610 of the low-pass filter path crosses the frequency response 620 of the high-pass filter path at approximately 2.5 GHz, which provides a phase shift of 90 degrees at approximately 2.5 GHz. This is illustrated in FIG. 6B which shows an exemplary phase-frequency curve 630 at the first output 436 and an exemplary phase-frequency curve 660 at the second output 438. In the example in FIG. 6B, the phase at the first output 436 at 2.5 GHz is approximately 104 degrees and the phase at the second output 438 at 2.5 GHz is approximately −166 degrees. Since one period (i.e., cycle) is 360 degrees, the phase at the second output 438 can be given as 194 degrees (i.e., 360-166 degrees), resulting in a phase shift of 90 degrees at 2.5 GHz in this example.

However, it is to be appreciated that the present disclosure is not limited to this example. In general, the frequency response 610 of the low-pass filter path and the frequency response 620 of the high-pass filter path may be designed to cross at a desired frequency (and hence provide a 90-degree phase shift at the desired frequency) by choosing the inductances of the inductors 450 and 452 and the capacitance between the inductors 450 and 452 (which is represented by the capacitors 510) accordingly. For example, the capacitance between the inductors 450 and 452 may be chosen based on the geometry of the inductors, the spacing between the inductors, and dielectric material between the inductors, etc.

Thus, the first inductor 450 and the second inductor 452 may be configured to provide approximately a 90-degree phase shift between the first input 412 of the main amplifier and the first input 422 of the auxiliary amplifier 420 at a frequency (e.g., center frequency) of the differential input RF signal. For example, the sizes of the inductors 450 and 452, the geometry of the inductors 450 and 452, the spacing between the inductors 450 and 452, and/or other parameters may be chosen to position the cross point at the frequency of the differential input RF signal. As used herein, the “cross point” is the frequency at which the frequency responses of the low-pass filter and the-high pass filter cross.

FIG. 5B shows a closeup view of the third inductor 454 and the fourth inductor 456 according to certain aspects. In this example, the third inductor 454 is coupled between the second input 434 and the third output 440, and the fourth inductor 456 is coupled between the node 455 (e.g., isolation node) and the fourth output 442. The fourth inductor 456 is also magnetically coupled with the third inductor 454.

The third inductor 454 and the fourth inductor 456 may each be implemented with a planar inductor (e.g., a planar spiral inductor, a loop inductor, etc.) integrated on the chip, in which the third inductor 454 and the fourth inductor 456 are placed close to each other to facilitate magnetic coupling between the third inductor 454 and the fourth inductor 456. The close proximity of the third inductor 454 and the fourth inductor 456 also results in capacitance between the third inductor 454 and the fourth inductor 456. In FIG. 5B, the capacitance is represented by the capacitors 520. FIG. 5B also shows capacitors representing the capacitance C_{main_in-} from the second input 414 of the main amplifier 410 and the capacitance C_{aux_in-} from the second input 424 of the auxiliary amplifier 420.

In this example, the second input RF signal RFᵢₙₙ is received at the second input 434 and split into RF signal RF_{Thru-} and RF signal RF_{CPL-}. The RF signal RF_{Thru-} propagates through the third inductor 454 along a path from the second input 434 to the third output 440. The RF signal RF_{Thru-} is coupled to the second input 414 of the main amplifier 410 (shown in FIG. 4). In this example, the first differential RF signal input to the main amplifier 410 includes the RF signals RF_{Thru+} and RF_{Thru-}.

The RF signal RF_{CPL-} propagates along a path from the second input 434 to the fourth output 442 via magnetic and capacitive coupling. The RF signal RF_{CPL-} is coupled to the second input 424 of the auxiliary amplifier 420 (shown in FIG. 4). In this example, the second differential RF signal input to the auxiliary amplifier 420 includes the RF signals RF_{CPL+} and RF_{CPL-}.

In this example, the path from the second input 434 to the third output 440 provides a low-pass filter path and the path from the second input 434 to the fourth output 442 provides a high-pass filter path. This is because the capacitors 520 act as shunt capacitors for path from the second input 434 to the third output 440 path and the capacitors 520 act as series capacitors for the path from the second input 434 to the fourth output 442. In this example, the phase shift between the low-pass filter path and the high-pass filter path (i.e., the third output 440 and the fourth output 442) is approximately 90 degrees at the frequency at which the frequency response of the low-pass filter path crosses the frequency response of the high-pass filter path.

In this regard, the frequency response of the low-pass filter path and the frequency response of the high-pass filter path may be designed to cross at a desired frequency (and hence provide a 90-degree phase shift at the desired frequency) by choosing the inductances of the inductors 454 and 456 and the capacitance between the inductors 454 and 456 (which is represented by the capacitors 520) accordingly. FIG. 6B shows an exemplary phase-frequency curve 650 at the third output 440 and an exemplary phase-frequency curve 640 at the fourth output 442, in which the phase shift is approximately 90 degrees at an exemplary cross point of 2.5 GHz. However, it is to be appreciated that the input circuit 430 is not limited to this example, and that the cross point may be located at different frequencies in other examples.

Thus, the third inductor 454 and the fourth inductor 456 may be configured to provide approximately a 90-degree phase shift between the first input 412 of the main amplifier and the first input 422 of the auxiliary amplifier 420 at the frequency (e.g., center frequency) of the differential input RF signal. For example, the sizes of the inductors 454 and 456, the geometry of the inductors 454 and 456, the spacing between the inductors 454 and 456, and/or other parameters may be chosen to position the cross point at the frequency of the differential input RF signal.

For the example where the inductors 450, 452, 454, and 456 are implemented with planar inductors integrated on a chip, the inductors 450, 454, 454, and 456 may be formed using lithography in which one or more metal layers are patterned to form the inductors 450, 452, 454, and 456 using one or more photo masks that define the patterning. In this example, the one or more photo masks may be generated based on the chosen sizes of the inductors 450, 452, 454, and 456, the geometry of the inductors 450, 452, 454, and 456, and the spacings between the inductors 450, 452, 454, and 456, and/or the like.

For the example where in the input circuit 430 includes the capacitors 470 and 472, the capacitances of the capacitors 470 and 742 may be tuned to tune the cross points of the phase generator 435. For example, in cases where the cross points deviate from a desired frequency (e.g., due to process variation), the capacitances of the capacitors 470 and 472 may be tuned to move the cross points closer to the desired frequency.

The exemplary input circuit 430 (also referred to as an input network) overcomes drawbacks of the RC-CR network and the input circuit that includes the transmission-line coupler and the two transformers at the inputs of the main amplifier and the auxiliary amplifier. For example, the input circuit 430 avoids the large signal losses in the RC-CR network due to the resistors in the RF signal paths of the RC-CR network. Also, the input circuit 430 eliminates the additional transformers at the inputs of the main amplifier and the auxiliary amplifier, which substantially reduces chip size. Also, the load at the phase generator 435 (e.g., the input capacitances of the main amplifier 410 and the auxiliary amplifier 420) can be easily handled by the phase generator 435. This is because the load can be absorbed into the phase generator 435 at the design stage by changing the inductances in the phase generator 435 without sacrificing signal loss and phase imbalance.

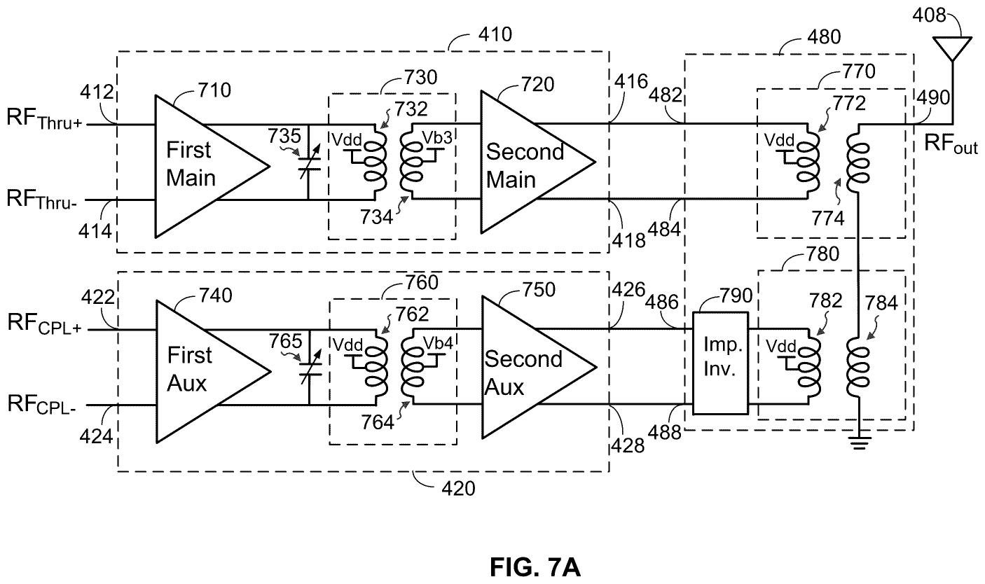

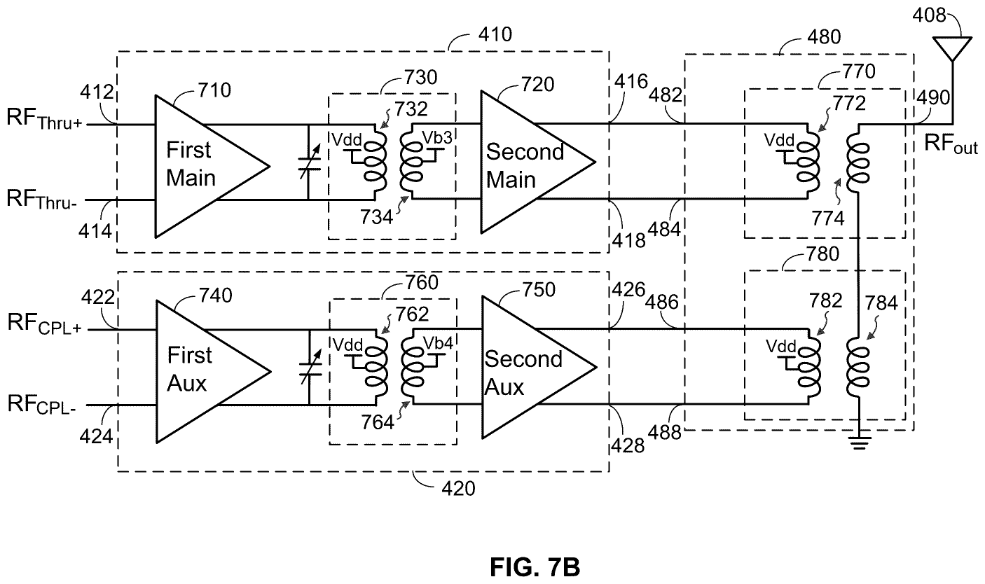

Each of the main amplifier 410 and the auxiliary amplifier 420 may include one or more stages. In this regard, FIG. 7A shows an example in which each of the main amplifier 410 and the auxiliary amplifier 420 includes two stages.

In this example, the main amplifier 410 includes a first main amplifier 710, a second main amplifier 720, and a transformer 730. The first main amplifier 710 has a differential input coupled to the inputs 412 and 414 and a differential output. The second main amplifier 720 has a differential input and a differential output coupled to the outputs 416 and 418.

In this example, the transformer 730 couples the differential output of the first main amplifier 710 to the differential input of the second main amplifier 720. The transformer 730 includes a first inductor 732 and a second inductor 734 magnetically coupled with the first inductor 732. The first inductor 732 is coupled to the differential output of the first main amplifier 710 and the second inductor 734 is coupled to the differential input of the second main amplifier 720. The center tap of the first inductor 732 may be biased by the supply voltage Vdd to DC bias the differential output of the first main amplifier 710, and the center tap of the second inductor 734 may be biased by bias voltage Vb3 to DC bias the differential input of the second main amplifier 720.

A shunt capacitor 735 may be coupled between the differential output of the first main amplifier 710 and the transformer 730 to tune the load of the first main amplifier 710 at a desired frequency to facilitate efficient transformer of power from the first main amplifier 710 to the second main amplifier 720.

In this example, the auxiliary amplifier 420 includes a first auxiliary amplifier 740, a second auxiliary amplifier 750, and a transformer 760. The first auxiliary amplifier 740 has a differential input coupled to the inputs 422 and 424 and a differential output. The second auxiliary amplifier 750 has a differential input and a differential output coupled to the outputs 426 and 428.

In this example, the transformer 760 couples the differential output of the first auxiliary amplifier 740 to the differential input of the second auxiliary amplifier 750. The transformer 760 includes a first inductor 762 and a second inductor 764 magnetically coupled with the first inductor 762. The first inductor 762 is coupled to the differential output of the first auxiliary amplifier 740 and the second inductor 764 is coupled to the differential input of the second auxiliary amplifier 750. The center tap of the first inductor 762 may be biased by the supply voltage Vdd to DC bias the differential output of the first auxiliary amplifier 740, and the center tap of the second inductor 764 may be biased by bias voltage Vb4 to DC bias the differential input of the second auxiliary amplifier 750.

A shunt capacitor 765 may be coupled between the differential output of the first auxiliary amplifier 740 and the transformer 760 to tune the load of the first auxiliary amplifier 740 at a desired frequency to facilitate efficient transformer of power from the first auxiliary amplifier 740 to the second auxiliary amplifier 750.

In the example in FIG. 7A, the output circuit 480 is implemented with a transformer-based output circuit including a first transformer 770 and a second transformer 780. The first transformer 770 includes a first inductor 772 and a second inductor 774 magnetically (i.e., inductively) coupled with the first inductor 772. The first inductor 772 is coupled between the first output 416 and the second output 418 of the main amplifier 410. The center tap of the first inductor 772 may be biased by the supply voltage Vdd to DC bias the differential output of the main amplifier 410.

The second transformer 780 includes a first inductor 782 and a second inductor 784 magnetically coupled with the first inductor 782. The output circuit 480 may include an impedance inverter 790 coupled between the differential output of the auxiliary amplifier 420 and the first inductor 782. However, as discussed further below, the impedance inverter 790 may be absorbed into the second transformer 780 to provide a more compact design in some implementations. The center tap of the first inductor 782 may be biased by the supply voltage Vdd to DC bias the differential output of the auxiliary amplifier 420.

In this example, the second inductor 784 of the second transformer 780 is coupled in series with the second inductor 774 of the first transformer 770 to provide voltage combining at the output 490. For example, the inductors 784 and 774 may be coupled in series between ground and the output 490 of the Doherty PA 400. As discussed above, an output circuit employing voltage combining may be referred to as a voltage-combining output circuit or network, a series output circuit or network, or another term.

FIG. 7B shows an example in which the impedance inverter 790 shown in FIG. 7A is absorbed into the transformer 780. In this example, the impedance inverter may be implemented with an inductor-capacitor (LC) network including inductors and capacitors (e.g., shunt capacitors) in which the inductors 782 and 784 of the transformer 780 implement the inductors to absorb the impedance inverter into the transformer 780. The capacitors may include the output capacitance of the auxiliary amplifier 420, parasitic capacitances, and/or capacitor devices (not shown in FIG. 7B).

FIGS. 7A and 7B show examples in which the output circuit 480 combines the output RF signals of the main amplifier 410 and the auxiliary amplifier 420 using voltage combining. However, it is to be appreciated that the output circuit 150 is not limited to voltage combining. For example, in other implementations, the output circuit 480 may be implemented with a current-combining output circuit.

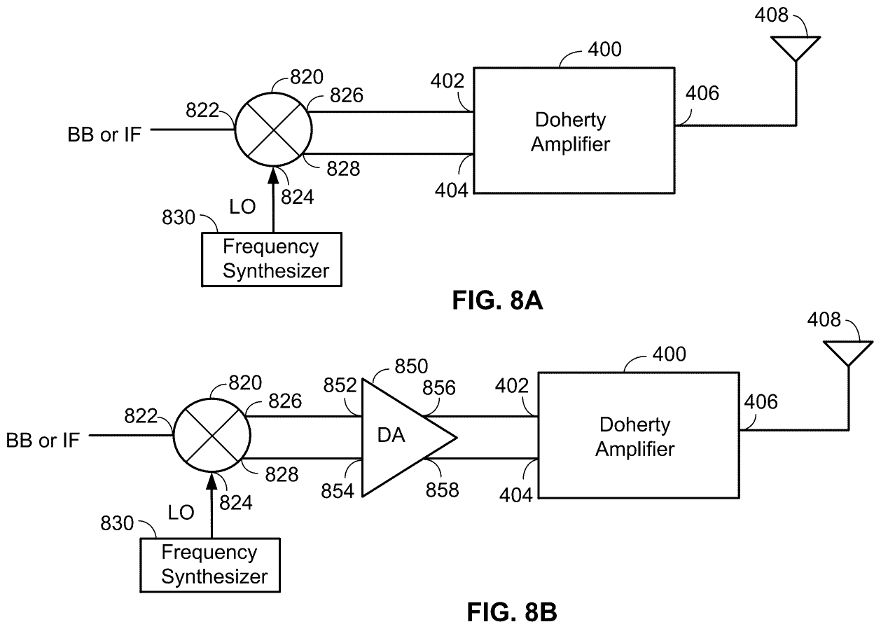

FIG. 8A shows an example of a mixer 820 coupled to the first input 402 and the second input 404 of the Doherty amplifier 400 to provide the differential input RF signal to the Doherty amplifier 400. In the example shown in FIG. 8A, the mixer 820 has a first input 822, a second input 824, and a differential output including a first output 826 and a second output 828. The mixer 820 is configured to receive a baseband signal (labeled “BB” in FIG. 8A) or an intermediate frequency (IF) signal at the first input 822 and a local oscillator signal (LO) at the second input 824. The LO signal is generated by a frequency synthesizer 830 (e.g., a phase-locked loop (PLL)) coupled to the second input 824 of the mixer 820. The mixer 820 and the Doherty amplifier 400 may be on separate chips or integrated on the same chip.

For the example in which the first input 822 of the mixer 820 receives the baseband signal, the first input 822 may be coupled to a baseband processor, a baseband filter, and the like. For the example in which the first input 822 of the mixer 820 receives the IF signal, the input 822 may be coupled an IF circuit configured to frequency upconvert a baseband signal into the IF signal. The IF signal has a frequency between baseband and the frequency of the input RF signal.

During operation, the mixer 820 receives the baseband signal or the IF signal at the first input 822 (which may be single-ended or differential) and receives the LO signal from the frequency synthesizer 830 at the second input 824. The mixer 820 mixes the baseband signal or the IF signal with the LO signal to frequency upconvert the baseband signal or the IF signal into an RF signal. In the example in FIG. 8A, the mixer 820 outputs the RF signal as a differential RF signal at the first and second outputs 826 and 828 of the mixer 820, which may be coupled to the first and second inputs 402 and 404, respectively, of the Doherty amplifier 400.

It is to be appreciated that the transmitter may include one or more additional components not shown in FIG. 8A. For example, FIG. 8B shows an example in which the transmitter also includes a driver amplifier 850 (also referred to as a driver stage) coupled between the mixer 820 and the Doherty amplifier 400 for driving the inputs 402 and 404 of the Doherty amplifier 400 with the RF signal from the mixer 820. In the example in FIG. 8B, the driver amplifier 850 has a differential input including a first input 852 and a second input 854 and a differential output including a first output 856 and a second output 858. The first input 852 and the second input 854 may be coupled to the first output 826 and the second output 828, respectively, of the mixer 820, and the first output 856 and the second output 858 may be coupled to the first input 402 and the second input 404, respectively, of the Doherty amplifier 400. The driver amplifier 850 and the Doherty amplifier 400 may be on separate chips or integrated on the same chip. In some implementations, the transmitter may also include an inter-stage transformer (not shown) between the mixer 820 and the Doherty amplifier 400.

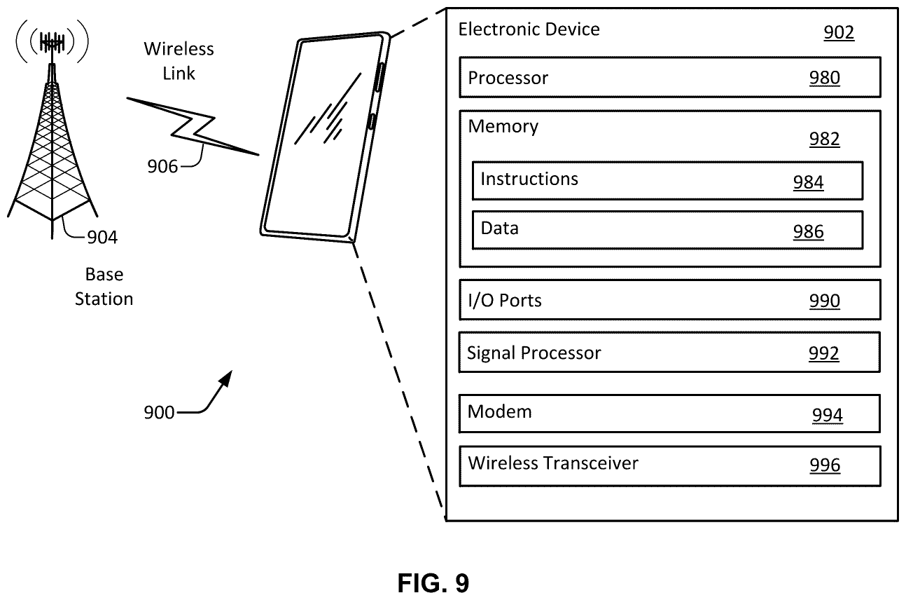

FIG. 9 is a diagram of an environment 900 that includes a wireless device 902 and a base station 904. In the environment 900, the wireless device 902 communicates with the base station 904 via a wireless link 906. As shown, the wireless device 902 is depicted as a smart phone. However, it is to be understood that the wireless device 902 may be implemented as any suitable wireless device, such as a cellular base station, a broadband router, an access point, a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

The base station 904 communicates with the wireless device 902 via the wireless link 906, which may be implemented as any suitable type of wireless link. Although depicted as a base station tower of a cellular radio network, the base station 904 may represent or be implemented as another device, such as a satellite, a terrestrial broadcast tower, an access point, a peer-to-peer device, a mesh network node, and so forth. The wireless link 906 may include a downlink of data and/or control information communicated from the base station 904 to the wireless device 902 and an uplink of other data and/or control information communicated from the wireless device 902 to the base station 904. The wireless link 906 may be implemented using any suitable communication protocol or standard, such as 3rd Generation Partnership Project Long-Term Evolution (3GPP LTE, 3GPP NR 5G), IEEE 902.99, IEEE 902.99, Bluetooth™, and so forth.

The wireless device 902 includes a processor 980 and a memory 982. The memory 982 may be or form a portion of a computer readable storage medium. The processor 980 may include any type of processor, such as an application processor or a multi-core processor, that is configured to execute processor-executable instructions stored in the memory 982. The memory 982 may include any suitable type of data storage media, such as a volatile memory (e.g., random access memory (RAM)), a non-volatile memory (e.g., Flash memory), an optical media, a magnetic media (e.g., disk or tape), or any combination thereof. In the context of this disclosure, the memory 982 may store instructions 984, data 986, and other information of the wireless device 902.

The wireless device 902 may also include input/output (I/O) ports 990. The I/O ports 990 enable data exchanges or interaction with other devices, networks, or users or between components of the wireless device 902.

The wireless device 902 may further include a signal processor (SP) 992 (e.g., such as a digital signal processor (DSP)). The signal processor 992 may function similar to the processor 980 and may be capable of executing instructions and/or processing information in conjunction with the memory 982.

For communication purposes, the wireless device 902 also includes a modem 994, a wireless transceiver 996, and one or more antennas (e.g., the antenna 408). The wireless transceiver 996 may include the Doherty amplifier 400, the mixer 820, and/or the driver amplifier 850 discussed above. The wireless transceiver 996 provides connectivity to respective networks (e.g., the base station 904) and other wireless devices connected therewith using RF signals. The wireless transceiver 996 may facilitate communication over any suitable type of wireless network, such as a wireless local area network (LAN) (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

Implementation examples are described in the following numbered clauses:

1. A Doherty power amplifier (PA), comprising:
a main amplifier;
an auxiliary amplifier;
a first inductor coupled between a first input of the Doherty PA and a first input of the main amplifier;
a second inductor coupled between a node and a first input of the auxiliary amplifier, wherein the second inductor is magnetically coupled with the first inductor;
a third inductor coupled between a second input of the Doherty PA and a second input of the main amplifier;
a fourth inductor coupled between the node and a second input of the auxiliary amplifier, wherein the fourth inductor is magnetically coupled with the third inductor; and
an output circuit coupled to an output of the main amplifier and an output of the auxiliary amplifier, wherein the output circuit is configured to combine an output radio frequency (RF) signal from the output of the main amplifier and an output RF signal from the output of the auxiliary amplifier into a combined RF signal.

2. The Doherty PA of clause 1, wherein the Doherty PA is configured to receive a differential input radio frequency (RF) signal including a first RF signal and a second RF signal, the first input of the Doherty PA is configured to receive the first RF signal, and the second input of the Doherty PA is configured to receive the second RF signal.

3. The Doherty PA of clause 2, wherein the second inductor and the fourth inductor are coupled in series between the first input of the auxiliary amplifier and the second input of the auxiliary amplifier.

4. The Doherty PA of clause 2 or 3, wherein the first inductor and the second inductor are configured to provide approximately a 90-degree phase shift between the first input of the main amplifier and the first input of the auxiliary amplifier at a frequency of the differential input RF signal.

5. The Doherty PA of clause 4, wherein the third inductor and the fourth inductor are configured to provide approximately a 90-degree phase shift between the second input of the main amplifier and the second input of the auxiliary amplifier at the frequency of the differential input RF signal.

6. The Doherty PA of any one of clauses 1 to 5, further comprising:
a first coupling capacitor coupling the first inductor to the first input of the main amplifier;
a second coupling capacitor coupling the second inductor to the first input of the auxiliary amplifier;
a third coupling capacitor coupling the third inductor to the second input of the main amplifier; and
a fourth coupling capacitor coupling the fourth inductor to the second input of the auxiliary amplifier.

7. The Doherty PA of any one of clauses 1 to 6, wherein the output circuit comprises a voltage-combining output circuit.

8. The Doherty PA of any one of clauses 1 to 6, wherein the output circuit comprises a current-combining output circuit.

9. The Doherty PA of any one of clauses 1 to 8, wherein the output circuit comprises:
a fifth inductor coupled to the output of the main amplifier;
a sixth inductor magnetically coupled with the fifth inductor;
a seventh inductor coupled to the output of the auxiliary amplifier;
an eighth inductor magnetically coupled with the seventh inductor, wherein the sixth inductor and the eighth inductor are coupled in series.

10. The Doherty PA of clause 9, wherein the sixth inductor and the eighth inductor are coupled in series between an output of the output circuit and a ground.

11. The Doherty PA of clause 10, wherein the output of the output circuit is coupled to an antenna.

12. The Doherty PA of any one of clauses 1 to 11, further comprising:
a first capacitor coupled between the first input of the main amplifier and the second input of the main amplifier; and
a second capacitor coupled between the first input of the auxiliary amplifier and the second input of the auxiliary amplifier.

13. The Doherty PA of clause 12, wherein the first capacitor comprises a first tunable capacitor and the second capacitor comprises a second tunable capacitor.

14. A system, comprising:
a mixer configured to mix a baseband signal or an intermediate frequency (IF) signal with a local oscillator (LO) signal to generate a differential input radio frequency (RF) signal including a first input RF signal and a second input RF signal; and
a Doherty power amplifier (PA) having a first input configured to receive the first RF signal and a second input configured to receive the second RF signal, the Doherty PA comprising:
   a main amplifier;
   an auxiliary amplifier;
a first inductor coupled between the first input of the Doherty PA and a first input of the main amplifier;
a second inductor coupled between a node and a first input of the auxiliary amplifier, wherein the second inductor is magnetically coupled with the first inductor;
a third inductor coupled between the second input of the Doherty PA and a second input of the main amplifier;
   a fourth inductor coupled between the node and a second input of the auxiliary amplifier, wherein the fourth inductor is magnetically coupled with the third inductor; and
an output circuit coupled to an output of the main amplifier and an output of the auxiliary amplifier, wherein the output circuit is configured to combine an output RF signal from the output of the main amplifier and an output RF signal from the output of the auxiliary amplifier into a combined RF signal.

15. The system of clause 14, further comprising an antenna coupled to an output of the output circuit.

16. The system of clause 14 or 15, wherein the second inductor and the fourth inductor are coupled in series between the first input of the auxiliary amplifier and the second input of the auxiliary amplifier.

17. The system of any one of clauses 14 to 16, wherein the first inductor and the second inductor are configured to provide approximately a 90-degree phase shift between the first input of the main amplifier and the first input of the auxiliary amplifier at a frequency of the differential input RF signal.

18. The system of clause 17, wherein the third inductor and the fourth inductor are configured to provide approximately a 90-degree phase shift between the second input of the main amplifier and the second input of the auxiliary amplifier at the frequency of the differential input RF signal.

19. The system of any one of clauses 14 to 18, wherein the output circuit comprises a voltage-combining output circuit.

20. The system of any one of clauses 14 to 18, wherein the output circuit comprises a current-combining output circuit.

21. The system of any one of clauses 14 to 20, wherein the output circuit comprises:
a fifth inductor coupled to the output of the main amplifier;
a sixth inductor magnetically coupled with the fifth inductor;
a seventh inductor coupled to the output of the auxiliary amplifier;
an eighth inductor magnetically coupled with the seventh inductor, wherein the sixth inductor and the eighth inductor are coupled in series.

22. The system of clause 21, wherein the sixth inductor and the eighth inductor are coupled in series between an output of the output circuit and a ground.

23. The system of clause 22 further comprising an antenna coupled to the output of the output circuit.

24. The Doherty PA of any one of clauses 14 to 23, further comprising:
a first capacitor coupled between the first input of the main amplifier and the second input of the main amplifier; and
a second capacitor coupled between the first input of the auxiliary amplifier and the second input of the auxiliary amplifier.

25. The system of clause 24, wherein the first capacitor comprises a first tunable capacitor and the second capacitor comprises a second tunable capacitor.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. It is also to be appreciated that an “inductor” may include multiple inductors coupled in series. It is also to be appreciated than an “input” may be a single-ended input, a differential input, or one of two inputs of a differential input, and an “output” may be a single-ended output, a differential output, or one of two outputs of a differential output. The term “approximately” means within a range of between 90 percent and 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A Doherty power amplifier (PA), comprising:
a main amplifier;
an auxiliary amplifier;
a first inductor coupled between a first input of the Doherty PA and a first input of the main amplifier;
a second inductor coupled between a node and a first input of the auxiliary amplifier, wherein the second inductor is magnetically coupled with the first inductor;
a third inductor coupled between a second input of the Doherty PA and a second input of the main amplifier;
a fourth inductor coupled between the node and a second input of the auxiliary amplifier, wherein the fourth inductor is magnetically coupled with the third inductor; and
an output circuit coupled to an output of the main amplifier and an output of the auxiliary amplifier, wherein the output circuit is configured to combine an output radio frequency (RF) signal from the output of the main amplifier and an output RF signal from the output of the auxiliary amplifier into a combined RF signal.

2. The Doherty PA of claim 1, wherein the Doherty PA is configured to receive a differential input radio frequency (RF) signal including a first RF signal and a second RF signal, the first input of the Doherty PA is configured to receive the first RF signal, and the second input of the Doherty PA is configured to receive the second RF signal.

3. The Doherty PA of claim 2, wherein the second inductor and the fourth inductor are coupled in series between the first input of the auxiliary amplifier and the second input of the auxiliary amplifier.

4. The Doherty PA of claim 2, wherein the first inductor and the second inductor are configured to provide approximately a 90-degree phase shift between the first input of the main amplifier and the first input of the auxiliary amplifier at a frequency of the differential input RF signal.

5. The Doherty PA of claim 4, wherein the third inductor and the fourth inductor are configured to provide approximately a 90-degree phase shift between the second input of the main amplifier and the second input of the auxiliary amplifier at the frequency of the differential input RF signal.

6. The Doherty PA of claim 1, further comprising:
a first coupling capacitor coupling the first inductor to the first input of the main amplifier;
a second coupling capacitor coupling the second inductor to the first input of the auxiliary amplifier;
a third coupling capacitor coupling the third inductor to the second input of the main amplifier; and
a fourth coupling capacitor coupling the fourth inductor to the second input of the auxiliary amplifier.

7. The Doherty PA of claim 1, wherein the output circuit comprises a voltage-combining output circuit.

8. The Doherty PA of claim 1, wherein the output circuit comprises a current-combining output circuit.

9. The Doherty PA of claim 1, wherein the output circuit comprises:
a fifth inductor coupled to the output of the main amplifier;
a sixth inductor magnetically coupled with the fifth inductor;
a seventh inductor coupled to the output of the auxiliary amplifier;
an eighth inductor magnetically coupled with the seventh inductor, wherein the sixth inductor and the eighth inductor are coupled in series.

10. The Doherty PA of claim 9, wherein the sixth inductor and the eighth inductor are coupled in series between an output of the output circuit and a ground.

11. The Doherty PA of claim 10, wherein the output of the output circuit is coupled to an antenna.

12. The Doherty PA of claim 1, further comprising:
a first capacitor coupled between the first input of the main amplifier and the second input of the main amplifier; and
a second capacitor coupled between the first input of the auxiliary amplifier and the second input of the auxiliary amplifier.

13. The Doherty PA of claim 12, wherein the first capacitor comprises a first tunable capacitor and the second capacitor comprises a second tunable capacitor.

14. A system, comprising:
a mixer configured to mix a baseband signal or an intermediate frequency (IF) signal with a local oscillator (LO) signal to generate a differential input radio frequency (RF) signal including a first input RF signal and a second input RF signal; and
a Doherty power amplifier (PA) having a first input configured to receive the first RF signal and a second input configured to receive the second RF signal, the Doherty PA comprising:
a main amplifier;
an auxiliary amplifier;
a first inductor coupled between the first input of the Doherty PA and a first input of the main amplifier;
a second inductor coupled between a node and a first input of the auxiliary amplifier, wherein the second inductor is magnetically coupled with the first inductor;
a third inductor coupled between the second input of the Doherty PA and a second input of the main amplifier;
a fourth inductor coupled between the node and a second input of the auxiliary amplifier, wherein the fourth inductor is magnetically coupled with the third inductor; and
an output circuit coupled to an output of the main amplifier and an output of the auxiliary amplifier, wherein the output circuit is configured to combine an output RF signal from the output of the main amplifier and an output RF signal from the output of the auxiliary amplifier into a combined RF signal.

15. The system of claim 14, further comprising an antenna coupled to an output of the output circuit.

16. The system of claim 14, wherein the second inductor and the fourth inductor are coupled in series between the first input of the auxiliary amplifier and the second input of the auxiliary amplifier.

17. The system of claim 14, wherein the first inductor and the second inductor are configured to provide approximately a 90-degree phase shift between the first input of the main amplifier and the first input of the auxiliary amplifier at a frequency of the differential input RF signal.

18. The system of claim 17, wherein the third inductor and the fourth inductor are configured to provide approximately a 90-degree phase shift between the second input of the main amplifier and the second input of the auxiliary amplifier at the frequency of the differential input RF signal.

19. The system of claim 14, wherein the output circuit comprises a voltage-combining output circuit.

20. The system of claim 14, wherein the output circuit comprises a current-combining output circuit.
